(19) United States
(12) Patent Application Publication
(10) Pub. No.: US 2025/0172883 A1
(43) Pub. Date: May 29, 2025

(54) EXHAUST DEVICE AND SUBSTRATE PROCESSING APPARATUS

(71) Applicant: SEMES CO., LTD., Cheonan-si (KR)

(72) Inventors: A Rah CHO, Daejeon (KR); Jong Wha KANG, Seongnam-si (KR); Woo Ram LEE, Seoul (KR); Byoung Doo CHOI, Cheonan-si (KR); Eun Hyeok CHOI, Cheonan-si (KR); Sung Gyu LEE, Suwon-si (KR); Da Mi CHONG, Cheonan-si (KR)

(21) Appl. No.: 18/884,099

(22) Filed: Sep. 12, 2024

(30) Foreign Application Priority Data
Nov. 29, 2023 (KR) 10-2023-0169879

(51) Int. Cl. G03F 7/00; G03F 7/16

(52) U.S. Cl. CPC G03F 7/70716; G03F 7/162

(57) ABSTRACT

Provided are an exhaust device and a substrate processing apparatus. The exhaust device includes a bowl disposed around a support unit supporting and rotating a substrate, an exhaust duct configured to surround a side portion of the bowl and connected to the side portion of the bowl, and a discharge duct formed outwardly of the exhaust duct, in a rotational direction of the support unit.

### CROSS-REFERENCE TO RELATED APPLICATIONS

This application claims benefit of priority to Korean Patent Application No. 10-2023-0169879 filed on Nov. 29, 2023 in the Korean Intellectual Property Office, the disclosure of which is incorporated herein by reference in its entirety.

### BACKGROUND

### 1. Field

The present disclosure relates to an exhaust device for exhausting gas within a process chamber and a substrate processing apparatus.

### 2. Description of Related Art

In order to manufacture semiconductor devices, various processes, such as cleaning, deposition, photo, etching, and ion implantation are performed. Among these processes, the photo process may include a coating process for forming a film by applying a photosensitive liquid, such as photoresist, to a surface of a substrate, an exposure process for transferring a circuit pattern to the film formed on the substrate, and a development process of selectively removing the film formed on the substrate from the exposed region or the opposite region.

A substrate processing facility used in the coating process for forming a film by applying a photosensitive liquid, such as photoresist, may include a cup-shaped bowl having a processing space, a support unit supporting and rotating the substrate in the processing space, and a nozzle unit supplying photoresist to the substrate seated on the support unit.

An exhaust unit is coupled to a bottom wall of the bowl to exhaust the atmosphere of the processing space. In general, the exhaust unit includes an integrated duct connecting a plurality of exhaust pipes respectively connected to a plurality of bowls, and a plurality of processing spaces may be exhausted simultaneously through the integrated duct.

### RELATED ART DOCUMENT

[Patent document]
(Patent document 1) Korean Application Publication No. 10-2023-0037879

### SUMMARY

An aspect of the present disclosure is to provide an exhaust device and a substrate processing apparatus capable of increasing exhaust efficiency by minimizing flow resistance of gas.

According to an aspect of the present disclosure, an exhaust device includes: a bowl disposed around a support unit supporting and rotating a substrate; an exhaust duct configured to surround a side portion of the bowl and connected to the side portion of the bowl; and a discharge duct formed outwardly of the exhaust duct, in a rotational direction of the support unit.

A plurality of communication holes may be formed on the side portion of the bowl and spaced apart from each other in a circumferential direction, and the bowl and the exhaust duct may be connected through the plurality of communication holes.

The plurality of communication holes may be formed to be spaced apart upwardly from an inner lower surface of the bowl.

The inner lower surface of the bowl may be formed to be inclined downwardly from the side portion of the bowl.

The discharge duct may be formed on one side and the other side of the exhaust duct, respectively.

The exhaust device may further include: a plurality of vanes arranged to be spaced apart from each other within the exhaust duct and formed to be inclined outwardly in the rotational direction of the support unit.

The vane may have a streamlined cross-section.

The vane may be configured to have a variable inclination angle.

According to another aspect of the present disclosure, a substrate processing apparatus includes: a process chamber; a support unit supporting and rotating a substrate within the process chamber; a nozzle unit discharging a chemical solution to the substrate; a bowl disposed around a periphery of the support unit; an exhaust duct configured to surround a side portion of the bowl and connected to the side portion of the bowl; and a discharge duct formed outwardly of the exhaust duct, in a rotational direction of the support unit.

According to another aspect of the present disclosure, a substrate processing apparatus includes: a process chamber; a support unit supporting and rotating a substrate within the process chamber; a nozzle unit discharging a chemical solution to the substrate; a bowl disposed around a periphery of the support unit and having a plurality of communication holes formed to be spaced apart from each other in a circumferential direction on a side portion thereof; an exhaust duct configured to surround a side portion of the bowl and connected to the side portion of the bowl through the plurality of communication holes; a discharge duct connected to the exhaust duct and formed outwardly of the exhaust duct, in a rotational direction of the support unit; and a plurality of vanes arranged to be spaced apart from each other within the exhaust duct and formed to be inclined outwardly in the rotational direction of the support unit.

### BRIEF DESCRIPTION OF DRAWINGS

The and other aspects, features, and advantages of the present disclosure will be more clearly understood from the following detailed description, taken in conjunction with the accompanying drawings, in which:

FIG. 1 is a perspective view illustrating an exhaust device according to the related art;

FIG. 2 is a perspective view illustrating a substrate processing facility according to an embodiment of the present disclosure;

FIG. 3 is a top view of the substrate processing facility of FIG. 2;

FIG. 4 is a view of the substrate processing facility of FIG. 3 in an A-A direction;

FIG. 5 is a view of the substrate processing facility of FIG. 3 in a B-B direction;

FIG. 6 is a cross-sectional view illustrating the inside of a substrate processing apparatus according to an embodiment of the present disclosure;

FIGS. 7 and 8 are perspective views illustrating an exhaust device of the substrate processing apparatus of FIG. 6;

FIGS. 9 and 10 are cross-sectional views illustrating the exhaust device of FIGS. 7 and 8;

FIG. 11 is a cut-away perspective view illustrating the exhaust device of FIGS. 7 and 8; and

FIG. 12 is an enlarged view of portion A of FIG. 11.

### DETAILED DESCRIPTION

Hereinafter, embodiments will be described in detail with reference to the accompanying drawings such that they may be easily practiced by those skilled in the art to which the present disclosure pertains. In describing the present disclosure, if a detailed explanation for a related known function or construction is considered to unnecessarily divert the gist of the present disclosure, such explanation will be omitted but would be understood by those skilled in the art. Also, similar reference numerals are used for the similar parts throughout the specification. In this disclosure, terms., such as “above,” “upper portion,” “upper surface,” “below,” “lower portion,” “lower surface,” “lateral surface,” and the like, are determined based on the drawings, and in actuality, the terms may be changed according to a direction in which a device or an element is disposed.

It will be understood that when an element is referred to as being “connected to” another element, it may be directly connected to the other element or intervening elements may also be present. In contrast, when an element is referred to as being “directly connected to” another element, no intervening elements are present. In addition, unless explicitly described to the contrary, the word “comprise” and variations thereof, such as “comprises” or “comprising,” will be understood to imply the inclusion of stated elements but not the exclusion of any other elements.

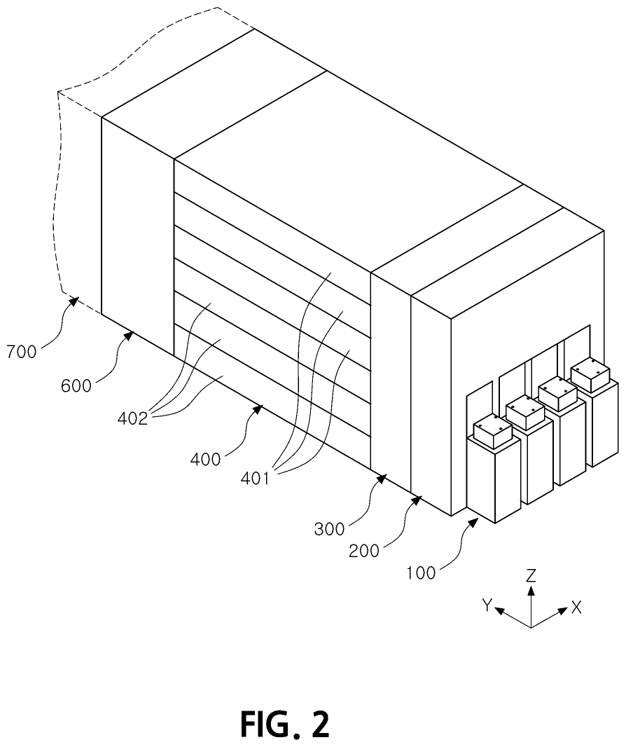

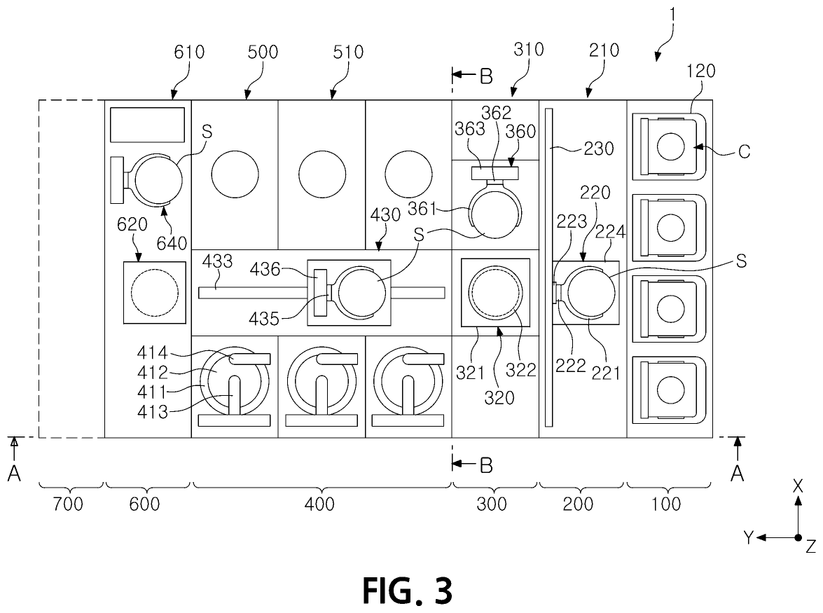

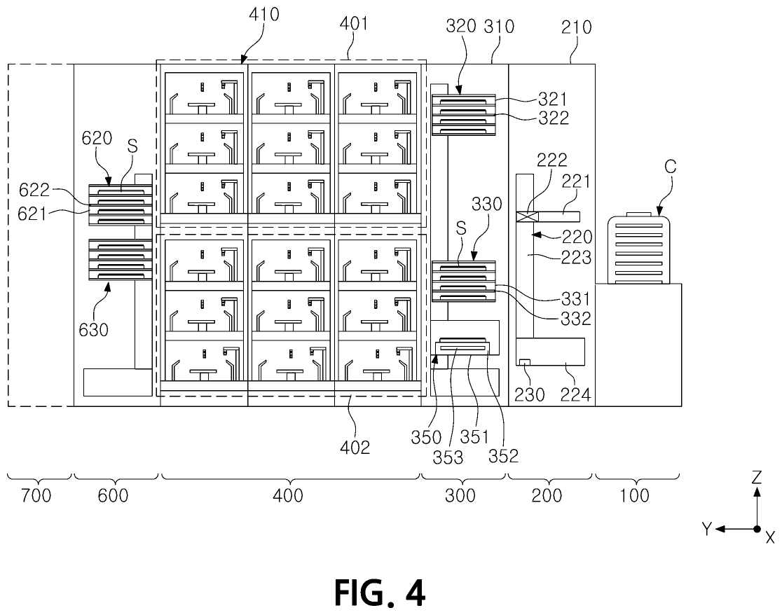

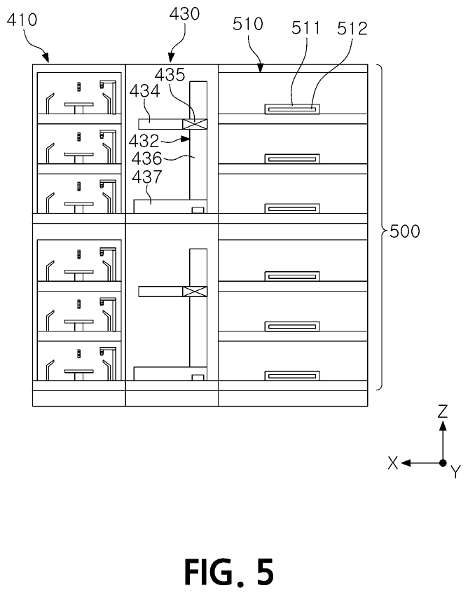

FIGS. 2 to 5 are drawings schematically illustrating a substrate processing facility according to an embodiment of the present disclosure, wherein FIG. 2 is a perspective view illustrating the substrate processing facility, FIG. 3 is a top view of the substrate processing facility of FIG. 2, FIG. 4 is a view of the substrate processing facility of FIG. 3 in an A-A direction, and FIG. 5 is a view of the substrate processing facility of FIG. 3 in a B-B direction.

Referring to FIGS. 2 to 5, a substrate processing facility 1 includes a load port 100, an index module 200, a buffer module 300, a coating and development module 400, and a purge module 800. The load port 100, the index module 200, the buffer module 300, the coating and development module 400, and the interface module 600 are sequentially disposed in a row in one direction.

Hereinafter, a direction in which the load port 100, the index module 200, the buffer module 300, the coating and development module 400, and the interface module 600 are disposed is referred to as a first direction Y, a direction, perpendicular to the first direction Y when viewed from above is referred to as a second direction X, and a direction, perpendicular to the first direction Y and the second direction X, is referred to as a third direction Z.

The substrate S is moved while stored in a cassette C. The cassette C has a structure that may be sealed from the outside. For example, a front open unified pod (FOUP) having a door at the front may be used as the cassette C.

Hereinafter, the load port 100, the index module 200, the buffer module 300, the coating and development module 400, and the interface module 600 are described in detail.

The load port 100 has a mounting plate 120 on which the cassette C including the substrate S is disposed. A plurality of mounting plates 120 are provided, and the mounting plates 120 are disposed in a row in the second direction X. In FIG. 3, an example in which four mounting plates 120 are provided is illustrated, but the number may be changed. The index module 200 transfers the substrate S between the cassette C disposed on the mounting plate 120 of the load port 100 and the buffer module 300. The index module 200 includes a frame 210, an index robot 220, and a guide rail 230. The frame 210 has a shape of a rectangular parallelepiped with a hollow interior and is disposed between the load port 100 and the buffer module 300. The frame 210 of the index module 200 may be provided at a height lower than the frame 310 of the buffer module 300. The index robot 220 and the guide rail 230 are disposed within the frame 210. The index robot 220 is provided such that a hand 221 for directly handling the substrate S may move and rotate in the first direction Y, the second direction X, and the third direction Z. The index robot 220 includes the hand 221, an arm 222, a support 223, and a pedestal 224. The hand 221 is fixedly installed on the arm 222. The arm 222 has an elastic structure and a rotatable structure. The support 223 is disposed so that a length direction thereof corresponds to the third direction Z. The arm 222 is coupled to the support 223 to be movable along the support 223. The support 223 is fixedly connected to the pedestal 224. The guide rail 230 is provided so that a length direction thereof corresponds to the second direction X. The pedestal 224 is coupled to the guide rail 230 to be movable in a straight line along the guide rail 230. In addition, although not shown, the frame 210 is further provided with a door opener for opening and closing a door of the cassette C.

The buffer module 300 includes a frame 310, a first buffer 320, a second buffer 330, a cooling chamber 350, and a first buffer robot 360. The frame 310 has a shape of a rectangular parallelepiped with a hollow interior and is disposed between the index module 200 and the coating and development module 400. The first buffer 320, the second buffer 330, the cooling chamber 350, and the first buffer robot 360 are located within the frame 310. The cooling chamber 350, the second buffer 330, and the first buffer 320 are sequentially disposed from below in the third direction Z. The first buffer 320 is located at a height corresponding to a coating module 401 of the coating and development module 400, and the second buffer 330 and the cooling chamber 350 are provided at a height corresponding to the development module 402 of the coating and development module 400. The first buffer robot 360 is located to be spaced apart by a predetermined distance from the second buffer 330, the cooling chamber 350, and the first buffer 320 in the second direction X. The first buffer 320 and the second buffer 330 each temporarily store a plurality of substrates S. The second buffer 330 has a housing 331 and a plurality of supports 332. The supports 332 are disposed in the housing 331 and are spaced apart from each other in the third direction Z. One substrate S is disposed on each support 332. The housing 331 has an opening in a direction in which the index robot 220 is provided and in a direction in which the first buffer robot 360 is provided so that the index robot 220 and the first buffer robot 360 may load or unload the substrate S into or from the supports 332 within the housing 331. The first buffer 320 has a structure substantially similar to that of the second buffer 330. However, the housing 321 of the first buffer 320 has an opening in the direction in which the first buffer robot 360 is provided and in the direction in which a coating part robot 432 located in an coating module 401 is provided. The number of supports 322 provided in the first buffer 320 and the number of supports 332 provided in the second buffer 330 may be the same or different. In an example, the number of supports 332 provided in the second buffer 330 may be greater than the number of supports 322 provided in the first buffer 320.

The first buffer robot 360 transfers the substrate S between the first buffer 320 and the second buffer 330 as illustrated in FIG. 3. The first buffer robot 360 includes a hand 361, an arm 362, and a support 363. The hand 361 is fixedly installed on the arm 362. The arm 362 has a flexible structure so that the hand 361 may move in the second direction X. The arm 362 is coupled to the support 363 so that it may move linearly in the third direction Z along the support 363. The support 363 has a length extending from a position corresponding to the second buffer 330 to a position corresponding to the first buffer 320. The support 363 may be provided to be longer in an upward or downward direction than this. The first buffer robot 360 may be provided so that the hand 361 may only be driven in two axes in the second direction X and the third direction Z.

The cooling chamber 350 cools each substrate S as illustrated in FIG. 4. The cooling chamber 350 includes a housing 351 and a cooling plate 352. The cooling plate 352 has an upper surface on which a substrate S is disposed and a cooling unit 353 cooling the substrate S. Various methods, such as cooling using cooling water or cooling using a thermoelectric device, may be used as the cooling unit 353. In addition, the cooling chamber 350 may include a lift pin assembly for locating the substrate S on the cooling plate 352. The housing 351 has an opening in the direction in which the index robot 220 is provided and in the direction in which the development part robot is provided so that the index robot 220 and the development part robot provided in the development module 402 may load or unload the substrate S onto or from the cooling plate 352. In addition, the cooling chamber 350 may include doors for opening and closing the aforementioned opening.

In the coating module 401, a process of applying a photosensitive liquid, such as photoresist, to the substrate S and a heat treatment process, such as heating and cooling, on the substrate S before and after a resist coating process are performed. The coating module 401 has a coating chamber 410, a bake chamber portion 500, and a transfer chamber 430. The coating chamber 410, the transfer chamber 430, and the bake chamber portion 500 are sequentially arranged in the second direction X. That is, with respect to the transfer chamber 430, the coating chamber 410 is provided on one side of the transfer chamber 430, and the bake chamber portion 500 is provided on the other side of the transfer chamber 430. A plurality of coating chambers 410 are provided, and the plurality of coating chambers 410 are provided in each of the first direction Y and the third direction Z. The bake chamber portion 500 includes a plurality of bake chambers 510, and the plurality of bake chambers 510 are provided in each of the first and the third direction Z. The transfer chamber 430 is located parallel to the first buffer 320 of the buffer module 300 in the first direction Y. The coating part robot 432 and a guide rail 433 are located inside the transfer chamber 430. The transfer chamber 430 has a substantially rectangular shape. The coating part robot 432 transfers the substrate S between the bake chamber 510, the coating chamber 410, and the first buffer 320 of the buffer module 300.

The guide rail 433 is located so that a length direction thereof is parallel to the first direction Y. The guide rail 433 guides the coating part robot 432 to move linearly in the first direction Y. The coating part robot 432 has a hand 434, an arm 435, a support 436, and a pedestal 437, as illustrated in FIG. 5. The hand 434 is fixedly installed on the arm 435. The arm 435 has an elastic structure so that the hand 434 may move in a horizontal direction. The support 436 is provided so that a length direction thereof corresponds to the third direction Z. The arm 435 is coupled to the support 436 so that the arm 435 may move linearly along the support 436 in the third direction Z. The support 436 is fixedly coupled to the pedestal 437, and the pedestal 437 is coupled to the guide rail 433 so that the pedestal 437 may move along the guide rail 433.

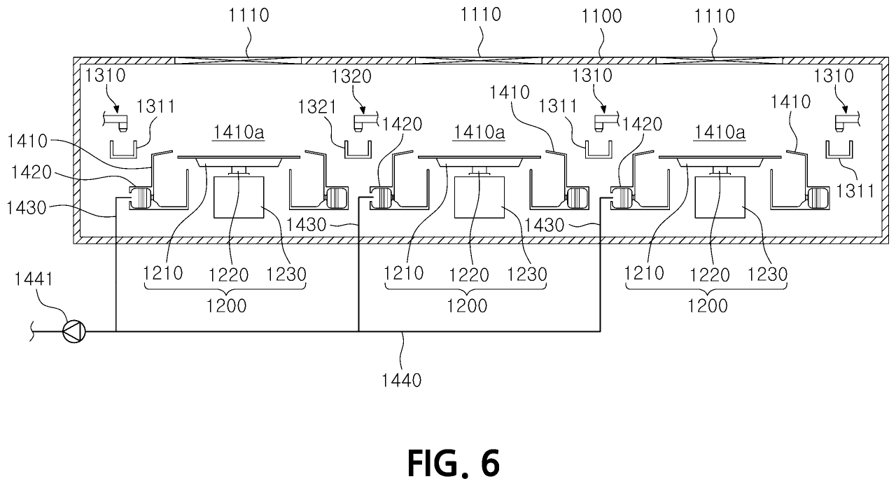

The coating chambers 410 may all have the same structure, but the type of a chemical solution used in each coating chamber 410 may be different from each other. The chemical solution may be a chemical solution for forming a photoresist film or an anti-reflection film. The substrate processing apparatus including the coating chamber 410 is described below with reference to FIG. 6.

The bake chamber 510 has a support unit 511 and a heater 512 built in the support unit 511 in an internal processing space, and the coating part robot 432 heat-treats the substrate S when the substrate S is disposed on the support unit 511. For example, the bake chamber 510 performs a prebake process in which the substrate S is heated to a predetermined temperature before applying photoresist to remove organic substances or moisture from the surface of the substrate S, a soft bake process performed after photoresist is applied to the substrate S, and a cooling process in which the substrate S is cooled after each heating process.

The interface module 600 connects the coating and development module 400 to an external exposure device 700. The interface module 600 includes an interface frame 610, a first interface buffer 620, a second interface buffer 630, and a transfer robot 640, and the transfer robot 640 transfers the substrate transferred to the first and second interface buffers 620 and 730 after coating and developing of the substrate is completed, to the external exposure device 700. The first and second interface buffers 620 and 730 include a housing 621 and a support 622, and the transfer robot 640 and the coating part robot 432 load/unload the substrate S to/from the support 622.

Hereinafter, the structure of the substrate processing apparatus including a process chamber is described in detail. As an example, a process chamber provided to the coating and development module is described. The process chamber may be a chamber forming a film, such as a protective film or an anti-reflection film on the substrate. In addition, the process chamber may be a chamber supplying a developing solution to the substrate to develop the substrate.

FIG. 6 is a cross-sectional view illustrating the inside of a substrate processing apparatus according to an embodiment of the present disclosure.

Referring to FIG. 6, the substrate processing apparatus 1000 may include a process chamber 1100, a support unit 1200, a nozzle unit 1300, and an exhaust device 1400.

The process chamber 1100 is provided in a rectangular cylinder shape having an internal space. An opening (not shown) 1 may be formed on one side of the process chamber 1100. The opening may function as a passage through which the substrate S is loaded or unloaded. A door (not shown) is installed in the opening, and the door may open and close the opening. A fan filter unit 1110 may be disposed on an upper wall of the process chamber 1100 to supply a descending airflow to the internal space. The fan filter unit 1110 may include a fan for introducing external air into the internal space and a filter filtering the external air. A plurality of fan filter units 1110 may be arranged above the plurality of bowls 1410, respectively. A plurality of support units and a plurality of nozzle units 1300 may be provided in the internal space of the process chamber 1100.

The support unit 1200 may support the substrate S in an internal space 1222 of the bowl 1410. In addition, the support unit 1200 may rotate the substrate S in the internal space 1222 of the bowl 1410. The support unit 1200 may include a support plate 1210, a driving shaft 1220, and a driving member 1230. An upper surface of the support plate 1210 may be provided in a circular shape. The support plate 1210 may have a diameter smaller than that of the substrate S. The support plate 1210 is provided to support the substrate S by vacuum pressure. Optionally, the support plate 1210 may have a mechanical clamping structure supporting the substrate S. A driving shaft 1220 may be coupled to the center of a bottom surface of the support plate 1210, and a driving member 1230 providing rotating force to the driving shaft 1220 may be provided to the driving shaft 1220. The driving member 1230 may be a motor.

The nozzle unit 1300 may supply a chemical solution onto the substrate S. The nozzle unit 1300 may include a first nozzle 1310 and a second nozzle 1320. A plurality of first nozzles 1310 may be provided and may supply the chemical solution to the substrate S provided to each of the support units 1200. The first nozzle 1310 may be provided to supply the same type of chemical solution. According to an embodiment, the first nozzle 1310 may supply a rinse solution for cleaning the substrate S. For example, the rinse solution may be water. In another embodiment, the first nozzle 1310 may supply a removing solution for removing photoresist from an edge region of the substrate S. For example, the removing solution may be a thinner. The first nozzle 1310 may be rotated between a process position and a standby position about a rotation axis thereof. The process position may be a position at which the chemical solution is discharged onto the substrate S, and the standby position may be a position at which the chemical solution is waited in a first standby port 1311 between the processing units 1201 when the chemical solution is not discharged from the first nozzle 1310. The second nozzle 1320 supplies a treatment solution to the substrate S provided to the support unit 1200. The treatment solution may be a photoresist. The second nozzle 1320 may be moved between a first process position, a second process position, a third process position, and the standby position along the guide. The first process position to the third process position may be positions for supplying the treatment solution to the substrate S supported by a plurality of support units 1200. The standby position may be a position for waiting in a second standby port 1321 located between the processing units 1201 when the photoresist is not discharged from the second nozzle not shown in the drawing, an elevator 1320. Although driving member for adjusting a relative height of the support plate 1210 and the bowl 1410 may be provided.

The exhaust device 1400 may include a bowl 1410, an exhaust duct 1420, and a discharge duct 1430.

Here, a plurality of bowls 1410 may be arranged in the process chamber 1100. Each of the plurality of bowls 1410 may have an internal space 1410a, and the internal space 1410a may be provided so that an upper portion thereof is open.

In addition, a plurality of exhaust ducts 1420 may be arranged to be installed in the plurality of bowls 1410, respectively. Each of the plurality of exhaust ducts 1420 may be connected to an integrated duct 1440 through the discharge duct 1430. The integrated duct 1440 may be disposed on one side based on an arrangement direction of the plurality of exhaust ducts 1420. That is, the integrated duct 1440 may be disposed so that a length direction thereof is parallel to the arrangement direction of the plurality of exhaust ducts 1420. The integrated duct 1440 may include a pressure reducing member 1441 providing a fluid pressure for exhaust. For example, the pressure reducing member 1441 may be a pump or a fan.

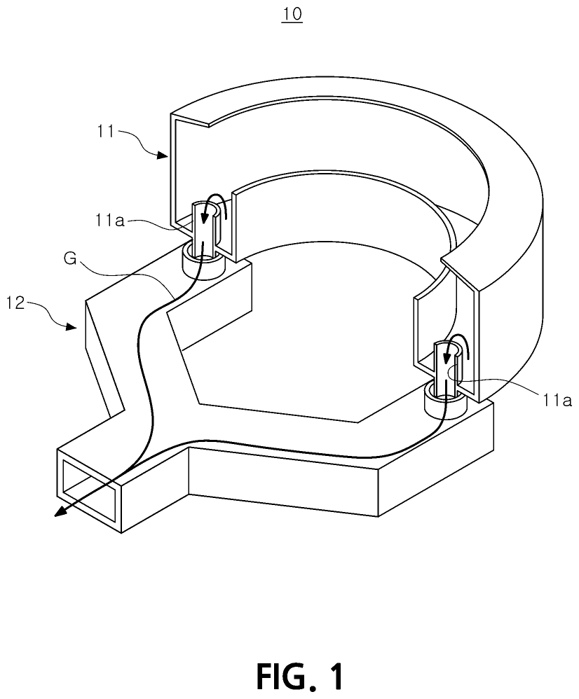

Meanwhile, before describing the exhaust device of the present disclosure in detail, the exhaust device of the related art is described with reference to FIG. 1 as follows.

In the exhaust device 10 of the related art, gas G flowing into the bowl 11 is exhausted to a lower side of the bowl 11. To this end, the exhaust duct 12 is connected to a lower portion of the bowl 11, and the exhaust duct 12 has a structure communicating with the bowl 11 by a gas exhaust portion 11a formed at a lower portion of the bowl 11. When the chemical solution is discharged onto the substrate through the nozzle unit, the support unit disposed inside the bowl 11 rotates the substrate. The substrate rotates due to the rotation of the support unit, and as a result, a rotating flow of gas G takes place in the internal space of the bowl 11. If the flow amount of the rotating gas G increases in this manner, the gas G cannot be smoothly exhausted to the exhaust duct 12 connected to the lower portion of the bowl 11. In order for the rotating gas G to be smoothly exhausted from the bowl 11, the gas G has to flow smoothly toward the exhaust duct 12 on the lower side, but the gas exhaust portion 11a which his vertically erected generates a significant flow resistance, preventing smooth exhaust. That is, in order for the gas G to pass through the gas exhaust portion 11a, the gas G flows upwardly along an outer surface of the gas exhaust portion 11a and then bent downwardly to flow to the inside of the gas exhaust portion 11a. However, due to the flow of the gas G, a significant flow resistance occurs.

As a result, the exhaust efficiency decreases within the bowl 11, and a vortex occurs, which causes a problem in that the substrate is not treated uniformly during the process.

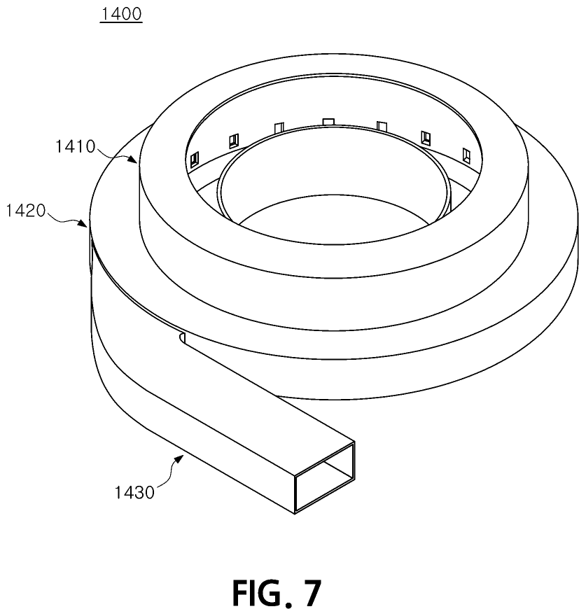

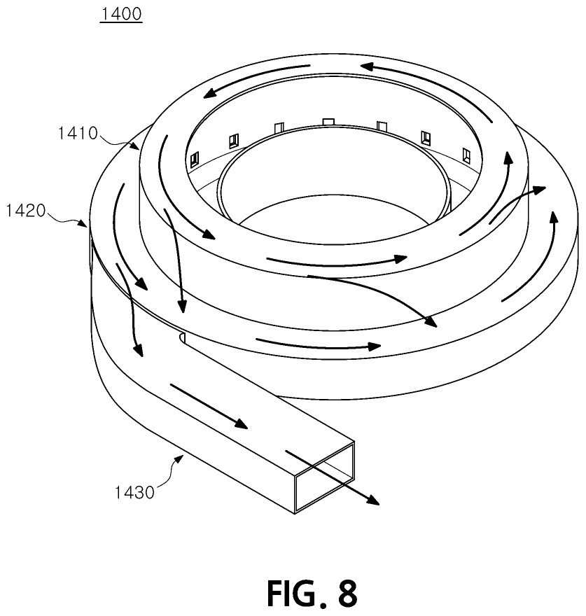

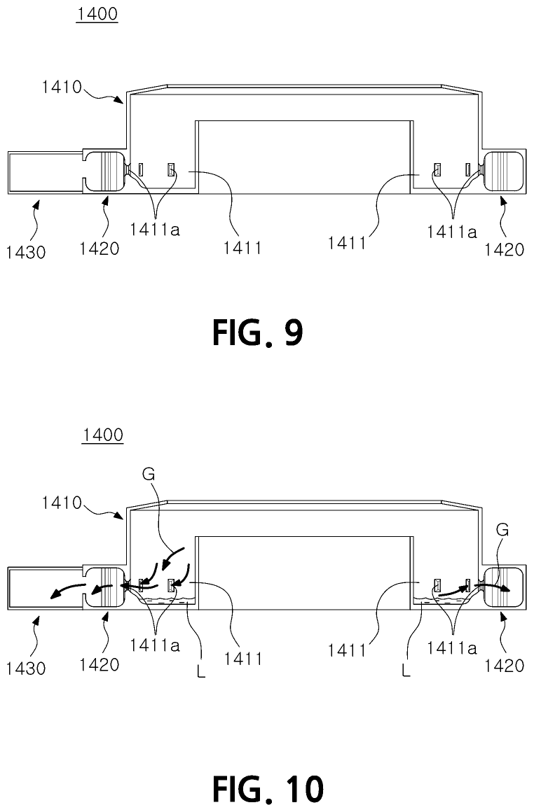

FIGS. 7 and 8 are perspective views illustrating the exhaust device of the substrate processing apparatus of FIG. 6, and FIGS. 9 and 10 are cross-sectional views illustrating the exhaust devices of FIGS. 7 and 8.

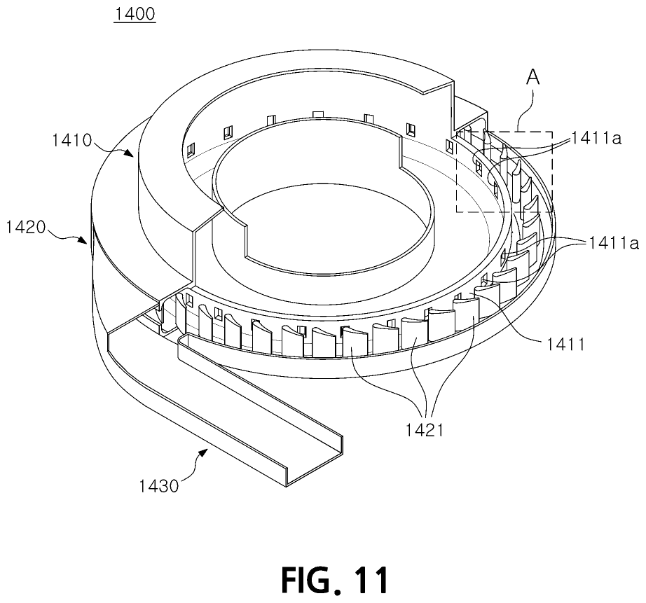

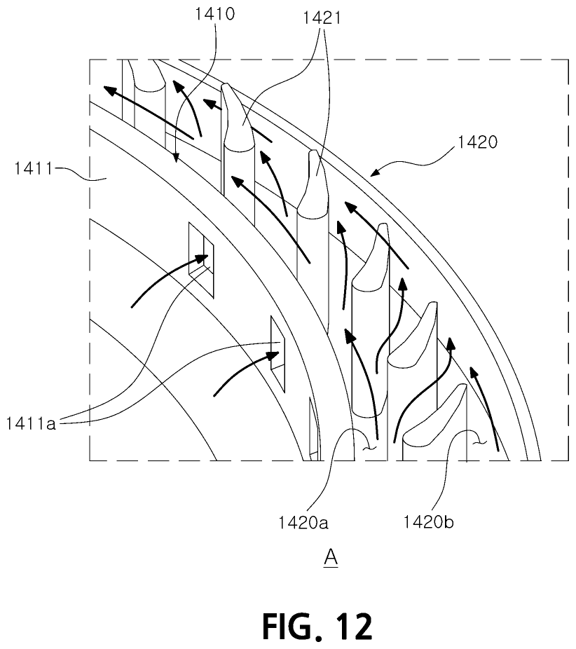

In addition, FIG. 11 is a cutaway perspective view illustrating the exhaust device of FIGS. 7 and 8, and FIG. 12 is an enlarged view of portion A of FIG. 11.

Referring to the drawings, an exhaust device 1400 according to an embodiment of the present disclosure is configured to exhaust gas G within the bowl 1410 without abrupt change in a flow direction in order to overcome the problems of the related art described above. That is, the exhaust device 1400 of the present disclosure adopts a structure in which the gas G within the bowl 1410 is exhausted in a horizontal direction, i.e., laterally, by using centrifugal force.

Specifically, in the present disclosure, the bowl 1410 of the exhaust device 1400 is disposed around the support unit, and the exhaust duct 1420 is installed in a side portion 1411 of the bowl 1410. That is, the exhaust duct 1420 is configured to surround the side portion 1411 of the bowl 1410 while being connected to the side portion 1411 of the bowl 1410 to exhaust the gas G rotating due to the rotation of the support unit laterally of the bowl 1410. Accordingly, in the exhaust device 1400 of the present disclosure, the gas G rotating in the bowl 1410 is exhausted laterally to the exhaust duct 1420 without abrupt change in flow direction by centrifugal force, thereby minimizing flow resistance to increase exhaust efficiency, and furthermore, forming a compact structure.

A plurality of communication holes 1411a are formed in the side portion 1411 of the bowl 1410, and the exhaust duct 1420 forms a structure communicating with the bowl 1410 by the plurality of communication holes 1411a. That is, the bowl 1410 and the exhaust duct 1420 may communicate with each other through the plurality of communication holes 1411a. In addition, the plurality of communication holes 1411a are disposed to be spaced apart from each other in a circumferential direction of the bowl 1410, and accordingly, the gas G inside the bowl 1410 flows uniformly to the exhaust duct 1420 through the plurality of communication holes 1411a during the rotation process.

In addition, a plurality of communication holes 1411a may be formed to be spaced apart upwardly from an inner lower surface of the bowl 1410. That is, the plurality of communication holes 1411a are formed at a certain height, not at the lower side, of the side portion 1411 of the bowl 1410, so that the chemical solution L and the gas G flowing into the bowl 1410 may be separated. In other words, the chemical solution L that has flowed into the inside of the bowl 1410 cannot pass through the communication hole 1411a and accumulates at the bottom of the bowl 1410 and is then discharged through a discharge pipe (not shown) connected to a lower portion of the bowl 1410. In addition, the gas G that has flowed into the inside of the bowl 1410 passes through the communication hole 1411a and flows to the exhaust duct 1420.

Furthermore, the inner lower surface of the bowl 1410 may be formed to be inclined downwardly from the side portion 1411 of the bowl 1410. In other words, the inner lower surface of the bowl 1410 may have a structure inclined downwardly direction from in a away the communication hole 1411a. This inclined structure serves to guide the chemical solution L that has flowed into the inside of the bowl 1410 away from the communication hole 1411a.

Also, in the present disclosure, the discharge duct 1430 of the exhaust device 1400 may be formed outwardly from the exhaust duct 1420 in a rotational direction of the support unit. If the discharge duct 1430 has a structure simply formed radially from the exhaust duct 1420, the gas G rotating inside the exhaust duct 1420 may not flow smoothly to the discharge duct 1430. Alternatively, if the discharge duct 1430 has a structure formed in a reverse rotational direction opposite to the rotational direction of the support unit, the gas G rotating inside the exhaust duct 1420 may not flow smoothly to the discharge duct 1430. However, the discharge duct 1430 of the present disclosure has a structure extending outwardly from the exhaust duct 1420 and corresponding to the rotational direction of the support unit, so that the gas G rotating in the exhaust duct 1420 may flow smoothly to the discharge duct 1430.

Furthermore, the discharge duct 1430 has a structure formed on one side portion of the exhaust duct 1420 in the drawing, but without being limited thereto, and although not shown in the drawing, the discharge duct 1430 may be formed on one side and the other side of the exhaust duct 1420. That is, by taking a structure in which the discharge duct 1430 is connected to each of one side and the other side of the exhaust duct 1420, which are opposite portions of the exhaust duct 1420, the flow amount from the exhaust duct 1420 to the discharge duct 1430 may be evenly divided, so that the gas G rotating in the exhaust duct 1420 may flow more smoothly to the discharge duct 1430.

Meanwhile, the exhaust device 1400 of the present disclosure may further include a vane 1421.

The vane 1421 may be disposed in plural, and the plurality of vanes 1421 may be arranged to be spaced apart from each other in the exhaust duct 1420. That is, the plurality of vanes 1421 may be arranged to be spaced apart from each other in the length direction of the exhaust duct 1420 in the exhaust duct 1420.

These vanes 1421 may be formed to be inclined outwardly in the rotational direction of the support unit. That is, the vanes 1421 may be arranged in the rotational direction of the support unit, and a rear end portion of the vanes 1421 in the rotational direction may be inclined outwardly at an acute angle based on the rotational direction. In other words, the vanes 1421 may be formed in a direction corresponding to the direction in which the rotating gas G receives centrifugal force and flows outwardly.

Accordingly, the gas G rotating in an internal space 1420a within the exhaust duct 1420 based on the plurality of vanes 1421 may smoothly pass between the plurality of vanes 1421 to the external space 1420b within the exhaust duct 1420. On the contrary, the gas G that has already passed and rotates in the external space 1420b within the exhaust duct 1420 based on the plurality of vanes 1421 has difficulty passing in the reverse direction between the plurality of vanes 1421 to the internal space 1420a within the exhaust duct 1420.

In addition, the vane 1421 may be formed in a streamlined cross-section. This streamlined shape refers to a shape in which a front portion of the vane 1421 has a curved shape based on the rotational direction of the gas G and becomes sharper toward a rear portion. Due to this, although the gas G collides with the plurality of vanes 1421 when flowing from the internal space 1420a to the external space 1420b within the exhaust duct 1420 based on the plurality of vanes 1421, flow resistance caused by the plurality of vanes 1421 may be minimized.

Furthermore, the vane 1421 may be configured such that an inclination angle varies. Considering various factors, such as the flow amount and rotational speed of the gas G within the exhaust duct 1420, the vane 1421 may be disposed at an appropriate inclination angle so that the gas G may most smoothly flow from the internal space 1420a to the external space 1420b within the exhaust duct 1420 based on the plurality of vanes 1421. In order to change the inclination angle of the vane 1421, the vane 1421 may be installed to rotate in the exhaust duct 1420 and may be rotated manually or automatically. The specific configuration for the rotation of the vane 1421 is not limited by the present disclosure, and any driving configuration of the related art may be utilized.

As a result, in the present disclosure, since the exhaust duct 1420 is configured to surround the side portion 1411 of the bowl 1410, while communicating with the side portion 1411 of the bowl 1410, the gas G rotating inside the bowl 1410 may flow to the exhaust duct 1420 in the lateral direction without an abrupt change in the flow direction due to centrifugal force, thereby minimizing the flow resistance to increase the exhaust efficiency, and furthermore, a compact structure may be obtained.

In the present disclosure, since the exhaust duct is configured to surround the side portion of the bowl, while communicating with the side portion of the bowl, the gas rotating inside the bowl may flow to the exhaust duct in the lateral direction without an abrupt change in the flow direction due to centrifugal force, thereby minimizing the flow resistance to increase the exhaust efficiency, and furthermore, a compact structure may be obtained.

While embodiments have been shown and described above, it will be apparent to those skilled in the art that modifications and variations could be made without departing from the scope e of the present disclosure as defined by the appended claims.

What is claimed is:

1. An exhaust device comprising:
a bowl disposed around a support unit supporting and rotating a substrate;
an exhaust duct configured to surround a side portion of the bowl and connected to the side portion of the bowl; and
a discharge duct formed outwardly of the exhaust duct, in a rotational direction of the support unit.

2. The exhaust device of claim 1, wherein a plurality of communication holes are formed on the side portion of the bowl and spaced apart from each other in a circumferential direction, and the bowl and the exhaust duct are connected through the plurality of communication holes.

3. The exhaust device of claim 2, wherein the plurality of communication holes are formed to be spaced apart upwardly from an inner lower surface of the bowl.

4. The exhaust device of claim 2, wherein the inner lower surface of the bowl is formed to be inclined downwardly from the side portion of the bowl.

5. The exhaust device of claim 1, wherein the discharge duct is formed on one side and the other side of the exhaust duct, respectively.

6. The exhaust device of claim 1, further comprising a plurality of vanes arranged to be spaced apart from each other within the exhaust duct and formed to be inclined outwardly in the rotational direction of the support unit.

7. The exhaust device of claim 6, wherein the vane has a streamlined cross-section.

8. The exhaust device of claim 6, wherein the vane is configured to have a variable inclination angle.

9. A substrate processing apparatus comprising:
a process chamber;
a support unit supporting and rotating a substrate within the process chamber;
a nozzle unit discharging a chemical solution to the substrate;
a bowl disposed around a periphery of the support unit;
an exhaust duct configured to surround a side portion of the bowl and connected to the side portion of the bowl; and
a discharge duct formed outwardly of the exhaust duct, in a rotational direction of the support unit.

10. The substrate processing apparatus of claim 9, wherein a plurality of communication holes are formed on the side portion of the bowl and spaced apart from each other in a circumferential direction, and the bowl and the exhaust duct are through the plurality of communication holes.

11. The substrate processing apparatus of claim 10, wherein the plurality of communication holes are formed to be spaced apart upwardly from an inner lower surface of the bowl.

12. The substrate processing apparatus of claim 10, wherein the inner lower surface of the bowl is formed to be inclined downwardly from the side portion of the bowl.

13. The substrate processing apparatus of claim 9, wherein the discharge duct is formed on one side and the other side of the exhaust duct, respectively.

14. The substrate processing apparatus of claim 9, further comprising a plurality of vanes arranged to be spaced apart from each other within the exhaust duct and formed to be inclined outwardly in the rotational direction of the support unit.

15. The substrate processing apparatus of claim 14, wherein the vane has a streamlined cross-section.

16. The substrate processing apparatus of claim 14, wherein the vane is configured to have a variable inclination angle.

17. A substrate processing apparatus comprising:
a process chamber;
a support unit supporting and rotating a substrate within the process chamber;
a nozzle unit discharging a chemical solution to the substrate;
a bowl disposed around a periphery of the support unit and having a plurality of communication holes formed to be spaced apart from each other in a circumferential direction on a side portion thereof;
an exhaust duct configured to surround a side portion of the bowl and connected to the side portion of the bowl through the plurality of communication holes;
a discharge duct connected to the exhaust duct and formed outwardly of the exhaust duct, in a rotational direction of support unit; and
a plurality of vanes arranged to be spaced apart from each other within the exhaust duct and formed to be inclined outwardly in the rotational direction of the support unit.

18. The substrate processing apparatus of claim 17, wherein
the plurality of communication holes are formed to be spaced apart upwardly from an inner lower surface of the bowl, and
the inner lower surface of the bowl is formed to be inclined downwardly from the side portion of the bowl.

19. The substrate processing apparatus of claim 17, wherein the vane has a streamlined cross-section.

20. The substrate processing apparatus of claim 17, wherein the vane is configured to have a variable inclination angle.
